(19) United States
(12) Patent Application Publication
(10) Pub. No.: US 2015/0098168 A1
(43) Pub. Date: Apr. 9, 2015

(54) SERVER CABINET

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: AN-GANG LIANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/141,329

(22) Filed: Dec. 26, 2013

(30) Foreign Application Priority Data
Oct. 9, 2013 (CN) 2013104662798

(51) Int. Cl. H05K 7/14

(52) U.S. Cl. CPC H05K 7/1491; H05K 7/1492
USPC 361/622

(57) ABSTRACT

A server cabinet includes a main body and a door. A number of servers is located in the main body. The door is rotatably connected to a front end of a side of the main body. The door includes a first power distribution unit arranged at an inner surface of the door.

### BACKGROUND

1. Technical Field

The present disclosure relates to a server cabinet.

2. Description of Related Art

Server cabinets are generally equipped with servers. Sometimes, there is very limited space in the server cabinets to install power distribution units. When the power distribution units are mounted in the server cabinets, the server cabinets are crowded, which causes heat to build up in the server cabinets that cannot be dissipated effectively.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of a server cabinet, wherein a door of the server cabinet is open.

FIG. 2 is an enlarged view of a circled portion II of FIG. 1.

FIG. 3 is an isometric view of the server cabinet of FIG. 1, wherein the door is close.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

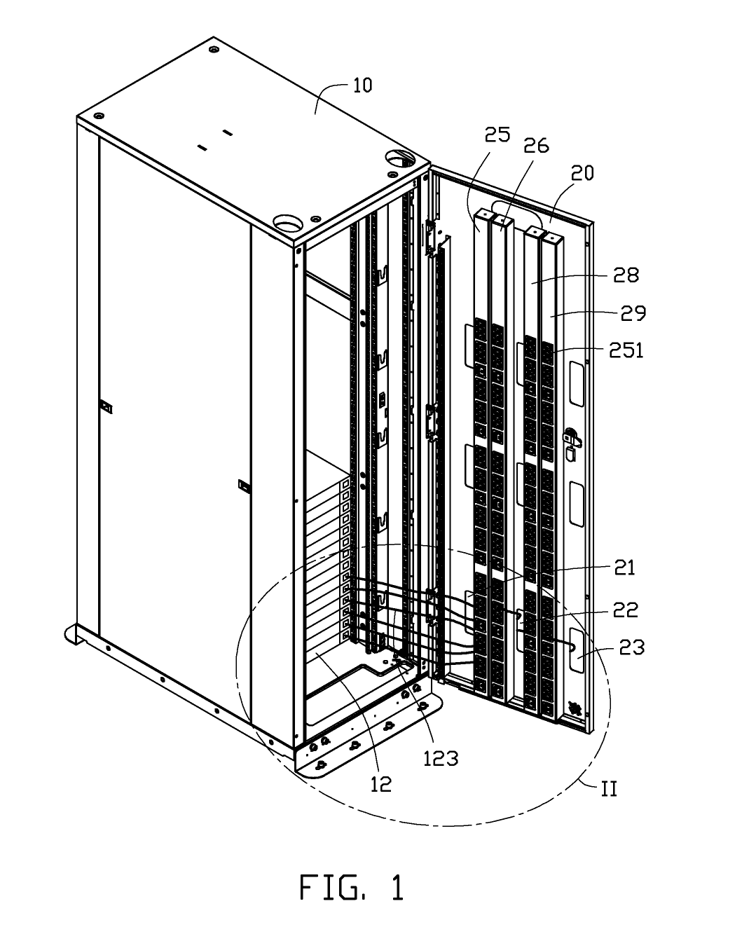

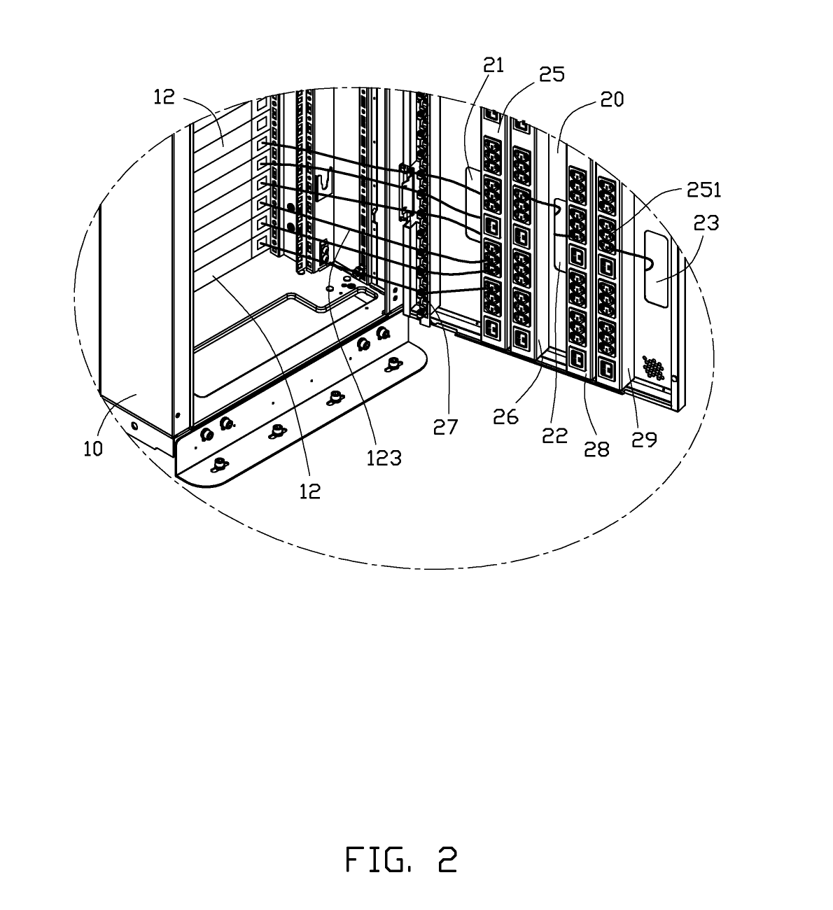

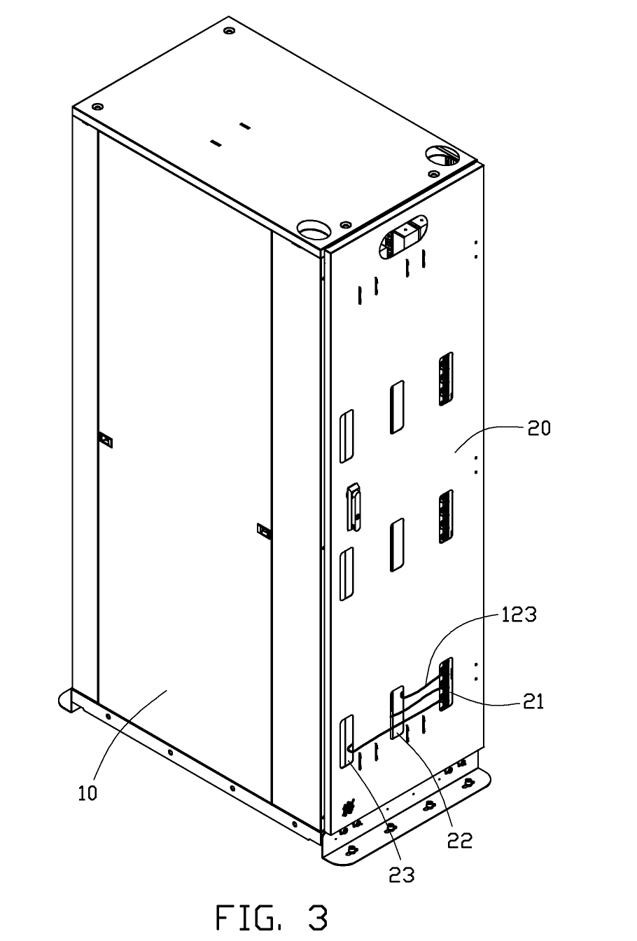

FIGS. 1 to 3 show an exemplary embodiment of a server cabinet including a main body 10 and a door 20.

A plurality of vertically aligned servers 12 is located in the main body 10. Each server 12 is connected to a power cord 123.

A first side of the door 20 is rotatably connected to a front end of a side of the main body 10. A plurality of vertically aligned cable clips 27 is mounted to an inner surface of the door 20 adjacent to the first side. The door 20 defines a plurality of vertically aligned first holes 21 adjacent to the cable clips 27, a plurality of vertically aligned second holes 22 in a middle of the door 20, and a plurality of vertically aligned third holes 23 adjacent to a second side of the door 20 away from the first side. A vertical first power distribution unit 25 and a vertical second power distribution unit 26 are arranged at the inner surface of the door 20 between the first holes 21 and the second holes 22, wherein the first power distribution unit 25 is adjacent to the first holes 21, and the second power distribution unit 26 is adjacent to the second holes 22. A vertical third power distribution unit 28 and a vertical fourth power distribution unit 29 are arranged at the inner surface of the door 20 between the second holes 22 and the third holes 23, wherein the third power distribution unit 28 is adjacent to the second holes 22, and the fourth power distribution unit 29 is adjacent to the third holes 23. Each of the first, second, third, and fourth power distribution units 25, 26, 28, and 29 includes a plurality of vertically aligned sockets 251.

In use, the power cords 123 of the servers 12 extend out of the main body 10 and are held by the corresponding cable clips 27 adjacent to the servers 12. Distal ends of the power cords 123 of a first part of the servers 12 are directly connected to the corresponding sockets 251 of the first power distribution unit 25. Distal ends of the power cords 123 of a second part of the servers 12 extend out of the door 20 through the adjacent first holes 21, and extend into the door 20 through the adjacent second holes 22, and then are connected to the corresponding sockets 251 of the second power distribution unit 26. Distal ends of the power cords 123 of a third part of the servers 12 extend out of the door 20 through the adjacent first holes 21, and extend into the door 20 through the adjacent second holes 22, and then are connected to the corresponding sockets 251 of the third power distribution unit 28. Distal ends of the power cords 123 of a fourth part of the servers 12 extend out of the door 20 through the adjacent first holes 21, and extend into the door 20 through the adjacent third holes 23, and then are connected to the corresponding sockets 251 of the fourth power distribution unit 29. Thereby, the power cords 123 of all the servers 12 are respectively connected to the first, second, third, and fourth power distribution units 25, 26, 28, and 29. The first, second, third, and fourth power distribution units 25, 26, 28, and 29 are arranged at the inner surface of the door 20, which can save space of the main body 10.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server cabinet, comprising:
a main body for mounting a plurality of servers; and
a door rotatably connected to a front end of a side of the main body, wherein the door comprises a first power distribution unit arranged at an inner surface of the door.

2. The server cabinet of claim 1, wherein the first power distribution unit is vertically arranged.

3. The server cabinet of claim 2, wherein the door comprises a first side rotatably connected to the front end of the side of the main body, the door defines a plurality of vertically aligned first holes adjacent to the first side, and a plurality of vertically aligned second holes away from the first side, the first power distribution unit is located between the first and second holes and adjacent to the first holes, the door further comprises a vertical second power distribution unit arranged at the inner surface of the door between the first and second holes and adjacent to the second holes.

4. The server cabinet of claim 3, wherein, when the plurality of severs are mounted in the server cabinet, each server is connected to a power cord, the power cords of a first part of the plurality of servers are directly connected to the first power distribution unit, and the power cords of a second part of the plurality of servers extend out of the door through the adjacent first holes, and extend into the door through the adjacent second holes, and then are connected to the second power distribution unit.

5. The server cabinet of claim 4, wherein the door further comprises a vertical third power distribution unit arranged at the inner surface of the door, the plurality of second holes are located between the second power distribution unit and the third power distribution unit, the power cords of a third part of the plurality of servers extend out of the door through the adjacent first holes, and extend into the door through the adjacent second holes, and then are connected to the third power distribution unit.

6. The server cabinet of claim 5, wherein the door defines a plurality of vertically aligned third holes adjacent to a second side of the door opposite to the first side, the door further comprises a vertical fourth power distribution unit arranged at the inner surface of the door adjacent to the plurality of third holes, the power cords of a fourth part of the plurality of servers extend out of the door through the adjacent first holes, and extend into the door through the adjacent third holes, and then are connected to the fourth power distribution unit.

7. The server cabinet of claim 4, wherein the door further comprises a plurality of vertically aligned cable clips arranged at the inner surface of the door between the first side and the plurality of first holes, the power cords of the plurality of servers are held by the plurality of cable clips.
